(19) United States
(12) Patent Application Publication
(10) Pub. No.: US 2010/0207137 A1
(43) Pub. Date: Aug. 19, 2010

(54) SEMICONDUCTOR DEVICE, SEMICONDUCTOR DEVICE MANUFACTURING METHOD, HIGH CARRIER MOBILITY TRANSISTOR AND LIGHT EMITTING DEVICE

(75) Inventors: Hiroyuki Sazawa, Ibaraki (JP); Yoshiaki Honda, Tsukuba-shi (JP)

Correspondence Address: FITCH, EVEN, TABIN & FLANNERY, P. O. BOX 18415, WASHINGTON, DC, 20036, US

(73) Assignee: Sumitomo Chemical Company, Limited, Chuo-ku Toyko (JP)

(21) Appl. No.: 12/669,164

(22) PCT Filed: Jul. 17, 2008
(86) PCT No.: PCT/JP2008/063335

§ 371 Date: Jan. 14, 2010

(30) Foreign Application Priority Data
Jul. 24, 2007 (JP) 2007-192684

(51) Int. Cl. H01L 33/12; H01L 29/12; H01L 21/20; H01L 29/778

(52) U.S. Cl. 257/94; 257/200; 438/478; 257/194; 257/E21.09; 257/E29.068; 257/E29.246; 257/E33.013; 257/E33.005

(57) ABSTRACT

Provided are a semiconductor device, a semiconductor device manufacturing method, a high carrier mobility transistor and a light emitting device. The semiconductor device is provided with a semiconductor layer including N and Ga, a conductive layer ohmic-connected to the semiconductor layer, a metal-distributed region where metal exists by being distributed at an interface between the semiconductor layer and the conductive layer, and a metal intrusion region where the atoms of the metal exist by entering the semiconductor layer.

### TECHNICAL FIELD

The present invention relates to a semiconductor device, a method of manufacturing semiconductor device, a high carrier mobility transistor, and a light emitting device. In particular, the present invention relates to a semiconductor device that reduces the contact resistance of an electrode that is ohmic-connected to a semiconductor layer, a method of manufacturing the semiconductor device, a high carrier mobility transistor, and a light emitting device.

### BACKGROUND ART

“Optimization of the Ti/Al/Ni/Au ohmic contact on AlGaN/GaN FET structures”, Journal of Crystal Growth, Vol. 241, 2002, pp. 15-18 by B. Jacob and others discloses a metal film composition, a metal film thickness, and an annealing condition that reduce the contact resistance of a metal electrode in a field effect transistor having a semiconductor structure of AlGaN and GaN. According to the document, a laminate structure of Ti, Al, Ni, and Au is adopted as a metal film composition, and the film thickness of the layers is set to be 30 nm, 180 nm, 40 nm and 150 nm respectively. Further, it is reported that a characteristic contact resistance of 7.3×10⁻⁷ Ωcm² has been obtained by executing a RTA (Rapid Thermal Annealing) treatment in a nitrogen atmosphere under a condition of 900° C. for 30 seconds.

### DISCLOSURE OF THE INVENTION

According to the technique disclosed in the above described document, reduction of the contact resistance can be realized by optimizing the structure of metal contact and the RTA treatment condition. However, as disclosed in the document, the contact resistance increases considerably when the condition is shifted from the optimal condition. The document merely discloses the optimization condition under a specific condition of metal contact with a main view to reducing the contact resistance. It is desired that a technique for reduction of contact resistance of metal contact that is not sensitive to the production condition is provided.

In order to solve the above described problems, the first embodiment of the present invention provides a semiconductor device having a semiconductor layer including N and Ga, a conductive layer ohmic-connected to the semiconductor layer, a metal-distributed region where metal exists by being distributed at an interface between the semiconductor layer and the conductive layer, and a metal intrusion region where the atoms of the metal exist by entering the semiconductor layer.

Here, the above-described summary of the invention does not mention all of the necessary characteristic features of the present invention. Further, a subcombination of the group of these characteristic features can also be an invention.

### BRIEF DESCRIPTION OF THE DRAWINGS

FIG. 1 shows a partial cross-section of a semiconductor device 100 of the present embodiment.

FIG. 2 shows one example of a cross-section in the steps of manufacturing the semiconductor device 100.

FIG. 3 shows one example of a cross-section in the steps of manufacturing the semiconductor device 100.

FIG. 4 shows one example of a cross-section in the steps of manufacturing the semiconductor device 100.

FIG. 5 shows one example of a cross-section in the steps of manufacturing the semiconductor device 100.

FIG. 6 shows one example of a cross-section in the steps of manufacturing the semiconductor device 100.

FIG. 7 shows the characteristic contact resistance and the Ti intrusion depth shown in Table 1 as a function of the Au film thickness.

FIG. 8 shows the characteristic contact resistance of Example 2 and Examples 5 to 7 as a function of the thermal treatment temperature.

FIG. 9 shows a TEM image obtained by observing the contact part of the semiconductor device 100 by the production condition of Example 2.

FIG. 10 shows a Ti mapping image by EDX with the same field of view as the TEM image of FIG. 9.

FIG. 11 shows a Ga mapping image by EDX with the same field of view as the TEM image of FIG. 9.

FIG. 12 shows an Al mapping image by EDX with the same field of view as the TEM image of FIG. 9.

FIG. 13 shows a TEM image in Comparative Example 1.

FIG. 14 shows a Ti mapping image by EDX with the same field of view as the TEM image of FIG. 13.

FIG. 15 shows a Ga mapping image by EDX with the same field of view as the TEM image of FIG. 13.

FIG. 16 shows an Al mapping image by EDX with the same field of view as the TEM image of FIG. 13.

FIG. 17 shows a light emitting device 300 as one example of the semiconductor device 100 of the present embodiment.

FIG. 18 shows a high carrier mobility transistor 400 as one example of the semiconductor device 100 of the present embodiment.

### DESCRIPTION OF THE SYMBOLS

100 semiconductor device
102 substrate
104 first semiconductor layer
106 second semiconductor layer
108 conductive layer
110 metal-distributed region
112 metal intrusion region
120 resist film
130 metal layer
132 diffusion-preventive layer
134 conductive layer
136 intermediate layer
138 cap layer
140 metal layer
142 diffusion-preventive layer
144 conductive layer
146 intermediate layer
148 cap layer
300 light emitting device
302 first semiconductor layer
304 second semiconductor layer
306 third semiconductor layer
308 electrode
310 metal-distributed region
312 metal intrusion region
314 transparent electrode
316 contact pad
400 high carrier mobility transistor
402 substrate
404 buffer layer
406 non-doped semiconductor layer
408 doped semiconductor layer
410 channel region
412 source electrode
414 metal-distributed region
416 metal intrusion region
418 drain electrode
420 metal-distributed region
422 metal intrusion region
424 gate electrode

### BEST MODES FOR CARRYING OUT THE INVENTION

Hereafter, the present invention will be described with reference to the embodiments of the present invention. However, the following embodiments do not limit the invention pertaining to the claims. Further, all of the combinations of the characteristic features described in the embodiments are not necessarily essential to the solution means of the invention.

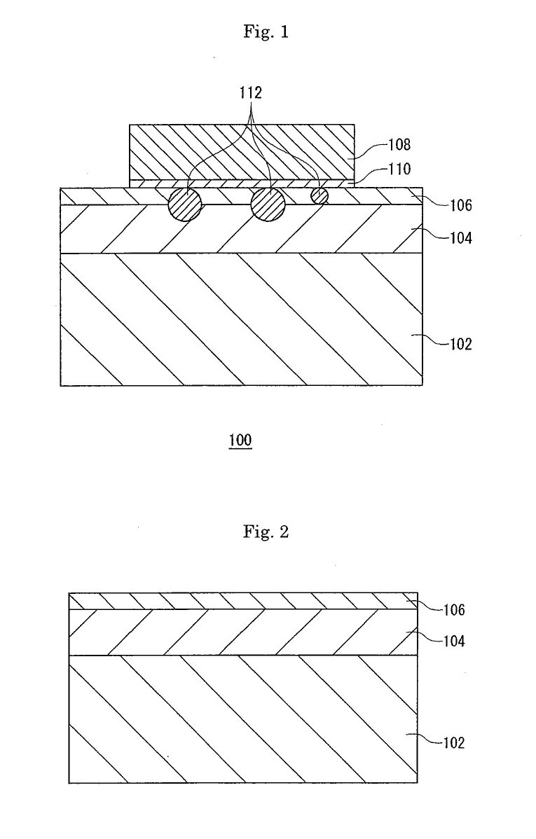

FIG. 1 shows a partial cross-section of a semiconductor device 100 of the present embodiment. The semiconductor device 100 of the present embodiment may be, for example, an FET (Field Effect Transistor), and the cross-section shown in FIG. 1 shows, for example, a contact part of the source or drain of the FET. The semiconductor device 100 includes a substrate 102, a first semiconductor layer 104, a second semiconductor layer 106, a conductive layer 108, a metal-distributed region 110, and a metal intrusion region 112.

The substrate 102 may be, for example, a single crystal Al₂O₃ (sapphire), SiC, Si, or the like, and may include an epitaxial growth layer of GaN single crystal on the surface of these single crystal Al₂O₃ and others. As an epitaxial growth method, metal organic chemical vapor deposition method and molecular beam epitaxial growth method, for example, can be shown.

The first semiconductor layer 104 and the second semiconductor layer 106 are examples of a semiconductor layer including N and Ga. The interface between the first semiconductor layer 104 and the second semiconductor layer 106 is an example of a hetero-junction interface of semiconductors including N and Ga. The first semiconductor layer 104 and the second semiconductor layer 106 may include a group III element, which is, for example, Al, constituting a mixed crystal by replacing Ga. Specifically, a semiconductor layer represented by AlₓGa₁₋ₓN (0≦x≦1) can be shown for the first semiconductor layer 104 and the second semiconductor layer 106. As the first semiconductor layer 104, a GaN layer (x=0 in the above formula), for example, can be shown. As the second semiconductor layer 106, an AlₓGa₁₋ₓN (0<x<1) layer, for example, can be shown.

The GaN layer and the AlGaN layer can be formed, for example, by an epitaxial growth method such as organic metal vapor deposition method or molecular beam epitaxial growth method. The GaN layer and the AlGaN layer may be an intrinsic semiconductor layer into which impurities are not introduced, or alternatively, an impurity becoming a conductivity type of P-type or N-type may be introduced.

The conductive layer 108 is ohmic-connected to the second semiconductor layer 106. The conductive layer 108 functions as an ohmic contact electrode of the semiconductor device 100. Further, the conductive layer 108 may be ohmic-connected to the first semiconductor layer 104 through the metal intrusion region 112. Al can be shown for the main component of the conductive layer 108. The conductive layer 108 can be formed, for example, by film formation using sputtering or vapor deposition of metal and patterning using photolithography method.

The conductive layer 108 may be, for example, a single layer of Al, or may have a multiple-layer laminate structure in which plural materials are laminated. For example, a conductive intermediate layer and a conductive cap layer may be formed on the conductive layer 108. The intermediate layer can be made to function as an adhesive layer or a compatibility preventive layer between the conductive layer 108 and the cap layer, and the cap layer can be made to function as an oxidation preventive layer or a ball-up preventive layer of the conductive layer 108. Ni, Ta, Nb, W, Pt, Mo, or Au can be shown for the intermediate layer. As the cap layer, Ni, Ta, Nb, W, Pt, Mo, or Au can be shown.

The metal-distributed region 110 exists at the interface between the second semiconductor layer 106 and the conductive layer 108. In the metal-distributed region 110, metal exists uniformly distributed. Ti can be shown for the metal distributed in the metal-distributed region 110. Here, the metal distributed in the metal-distributed region 110 does not exist only in the metal-distributed region 110, but may exist also in the conductive layer 108.

The metal intrusion region 112 exists at least in the second semiconductor layer 106. In the metal intrusion region 112, atoms of a metal of the same kind as the metal distributed in the metal-distributed region 110 exist by entering the metal intrusion region 112. The metal intrusion region 112 may exist also in the first semiconductor layer 104 by penetrating through the second' semiconductor layer 106. Here, in FIG. 1, the cross-sectional shape of the metal intrusion region 112 is displayed in a circular shape for convenience sake; however, the shape is not limited to a circular shape.

In the semiconductor device 100 of the present embodiment, the metal intrusion region 112 is formed in the second semiconductor layer 106 that is a semiconductor layer, so that it can reduce the contact resistance of the conductive layer 108 functioning as an ohmic contact electrode. The effect of reducing the contact resistance is obtained by a physical property such that the metal intrusion region 112 is formed, and the effect exceeds the effect obtained by optimization of the production processing condition.

As the metal entering the metal intrusion region 112, Ti can be shown. Ti may be bounded with N contained in the first semiconductor layer 104 or the second semiconductor layer 106 to constitute TiN. Since TiN has a small work function, the barrier between the metal and the semiconductor can be reduced to reduce further the contact resistance by that Ti in the metal intrusion region 112 constitutes TiN.

The metal intrusion region 112 is formed non-uniformly in a plane parallel to the interface with the second semiconductor layer 106 which is a semiconductor layer. Accordingly, the contact area between the metal intrusion region 112 and the first semiconductor layer 104 or the second semiconductor layer 106 will be large, thereby reducing the contact resistance. In addition, the metal intrusion region 112 is formed to reach a region having an intrusion depth of 6 nm or more in the second semiconductor layer 106. By this, the contact area in the semiconductor layer of the metal intrusion region 112 can be increased, thereby reducing the contact resistance.

The metal intrusion region 112 may be formed to reach the junction interface between the first semiconductor layer 104 and the second semiconductor layer 106, that is, a hetero-junction interface. When applied to a device such as a high electron mobility transistor in which a two-dimensional electron gas is formed at the hetero-junction interface as a channel, the conductive layer 108 and the channel region can be connected by the metal intrusion region 112 having a low resistance. As a result thereof, the resistance of a path starting from the conductive layer 108 and reaching the channel region can be reduced.

The metal intrusion region 112 may be formed in a region of the semiconductor layer that does not reach the hetero-junction interface, that is, in the second semiconductor layer 106. For example, in the case of forming a quantum well by plural hetero-junctions, the scattering of the carriers by the intruding metal within the quantum well can be restrained.

The metal entering the metal intrusion region 112 may exist more in the metal intrusion region 112 as compared with the conductive layer 108. Further, the concentration of the metal in the metal intrusion region 112 may be within a range of 1% or more and less than 100% in terms of molar fraction. The concentration of Ga in the metal intrusion region 112 may be lower than the concentration of Ga in the first semiconductor layer 104 and the second semiconductor layer 106 other than the metal intrusion region 112, and may be formed to be lower, for example, by 50% or more. A group III element, for example, Al, may exist in the surroundings of the metal intrusion region 112. In other words, a group III element, for example, Al, may exist surrounding the metal intrusion region 112 in the first semiconductor layer 104 and the second semiconductor layer 106.

These characteristic features of the metal intrusion region 112 can be obtained by the fact that the metal-distributed region 110 and the metal intrusion region 112 are formed by the following method. That is, a metal layer containing a metal (for example, Ti) as a main component is formed on the first semiconductor layer 104 and the second semiconductor layer 106. A diffusion preventive layer for preventing diffusion of the metal (for example, Ti) constituting the metal layer is formed. Further, by forming a conductive layer 108 and thermally treating the metal layer, the diffusion preventive layer, and the conductive layer 108, the metal-distributed region 110 and the metal intrusion region 112 are formed. The material constituting the diffusion preventive layer may have a melting point higher than a melting point of the material, which constitutes the conductive layer 108, for example, Al.

FIGS. 2 to 6 show examples of a cross-section in the steps of manufacturing the semiconductor device 100. As shown in FIG. 2, a second semiconductor layer 106, example of which is AlGaN, is further formed, after a first semiconductor layer 104, example of which is GaN, is formed on a substrate 102, example of which is sapphire. The first semiconductor layer 104 and the second semiconductor layer 106 can be formed by an epitaxial growth method such as organic metal vapor deposition method or molecular beam epitaxial growth method. Example of the film thickness of the first semiconductor layer 104 is 2 μm and example of the film thickness of the second semiconductor layer 106 is 30 nm. Into the first semiconductor layer 104 and the second semiconductor layer 106, an impurity to be a donor or an acceptor can be suitably introduced in accordance with the device construction of the semiconductor device 100.

As shown in FIG. 3, a patterned resist film 120 is formed on the second semiconductor layer 106. The resist film 120 is patterned by applying a resist on the entire surface of the second semiconductor layer 106 and performing photolithography so that an opening may be formed in a region where the conductive layer 108 is to be formed. Here, before forming the resist film 120 for forming the conductive layer 108, the process according to the device construction of the semiconductor device 100 can be completed. For example, processes such as ion implantation of an impurity into the source region and drain region of a FET, annealing, and forming a gate electrode may be completed.

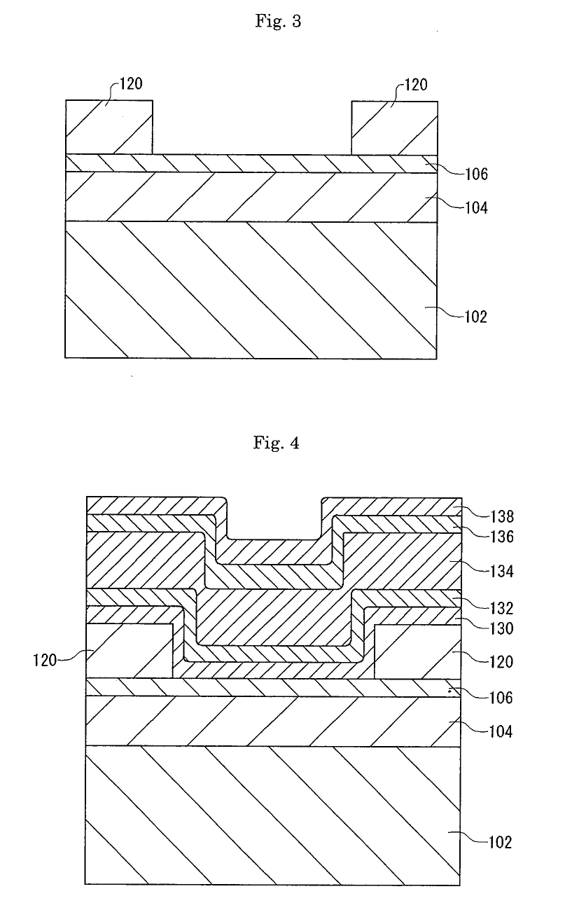

As shown in FIG. 4, a metal layer 130, a diffusion preventive-layer 132, a conductive layer 134, an intermediate layer 136, and a cap layer 138 are successively formed on the second semiconductor layer 106 on which the resist film 120 has been formed. The metal layer 130, the diffusion preventive layer 132, the conductive layer 134, the intermediate layer 136, and the cap layer 138 can be formed, for example, by a metal thin film deposition method such as vapor deposition method, sputtering method, or the like. The metal layer 130 includes a metal that forms the metal-distributed region 110 and the metal intrusion region 112. The diffusion preventive layer 132 prevents diffusion of the metal constituting the metal layer 130. The conductive layer 134 is processed to become a conductive layer 108.

Ti can be shown for the metal mainly constituting the metal layer 130. The film thickness of the Ti layer can be 20 nm. Al can be shown for the material mainly constituting the conductive layer 134. The film thickness of the Al layer can be 180 nm. Ni can be shown for the metal mainly constituting the intermediate layer 136. The film thickness of the Ni layer can be 25 nm. Au can be shown for the metal mainly constituting the cap layer 138. The film thickness of the Au layer can be 30 nm. Here, as the material constituting the intermediate layer 136 and the cap layer 138, Ta, Nb, W, Pt, or Mo can be applied besides the above.

The material constituting the diffusion preventive layer 132 has a melting point higher than a melting point of the material constituting the conductive layer 134. Since the diffusion-preventive layer 132 has a higher melting point than the conductive layer 134, the diffusion of the metal constituting the metal layer 130 into the conductive layer 134 can be prevented even in a state in which the conductive layer 134 is melted. The material mainly constituting the diffusion preventive layer 132 can be exemplified by Au, Ag, Cu, W, Mo, Cr, Nb, Pt, Pd and Si. Among the above described metals, Au, Ag, Cu, Pt, Pd, and Si are preferable. Further, as the material mainly constituting the diffusion-preventive layer 132, Au, Ag, Cu, and Si are more preferable, and Au is particularly preferable.

The diffusion-preventive layer 132 may be any material selected from the above described Au, Ag, Cu, W, Mo, Cr, Nb, Pt, Pd, and Si, an alloy of these, or a nitride or oxide of these. Among these, any one of the metals or an alloy of these is preferable. The diffusion-preventive layer 132 can be formed to have a film thickness of 10 nm or more and 500 nm or less, preferably 15 nm or more and 200 nm or less, more preferably 25 nm or more and 80 nm or less.

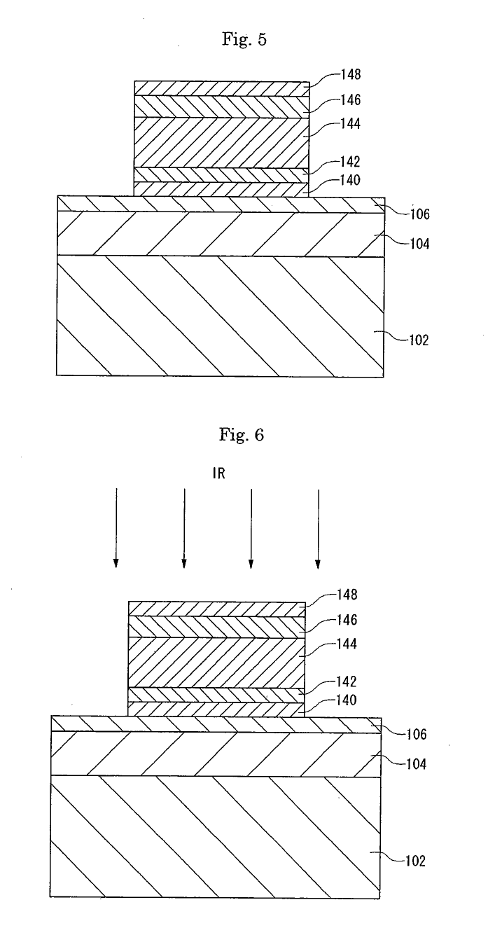

As shown in FIG. 5, the patterned metal layer 140, diffusion-preventive layer 142, conductive layer 144, intermediate layer 146, and cap layer 148 are formed, for example, by peeling the resist film 120 off. Here, the patterning by the lift-off method by peeling the resist film 120 off is shown; however, the patterning may be executed by dry etching or the like.

As shown in FIG. 6, after the metal layer 140, the diffusion-preventive layer 142, the conductive layer 144, the intermediate layer 146, and the cap layer 148 are formed, a thermal treatment by RTA is performed, for example. By the thermal treatment, the metal layer 140 is melted or softened, and the metal constituting the metal layer 140 is diffused into the first semiconductor layer 104 and the second semiconductor layer 106. On the other hand, since the diffusion-preventive layer 142 exists on the metal layer 140, the diffusion of the metal constituting the metal layer 140 in the direction of the conductive layer 144 is restrained. For this reason, the metal constituting the metal layer 140 receives a stronger concentration gradient to be diffused in the direction of the first semiconductor layer 104 and the second semiconductor layer 106. As a result of this, the metal-distributed region 110 and the metal intrusion region 112 are formed.

There are cases in which, by the above thermal treatment, the conductive layer 144 also is melted or softened, whereby the diffusion-preventive layer 142, the intermediate layer 146, and the cap layer 148 are melted to such a degree of not retaining the original shape. In such a case, the conductive layer 108 formed as a result of the thermal treatment will be formed to include the elements constituting these diffusion-preventive layer 142, intermediate layer 146, and cap layer 148 in addition to the elements constituting the conductive layer 144. Here, even in a case in which the intermediate layer 146 and the cap layer 148 are not formed, the semiconductor device 100 of the present embodiment can be constructed. In such a case, the conductive layer 108 naturally formed as a result of the thermal treatment does not include the elements constituting the intermediate layer 146 and the cap layer 148.

The thermal treatment can be executed within a temperature range of 650° C. or higher and 900° C. or lower, preferably within a temperature range of 750° C. or higher and 900° C. or lower, more preferably within a temperature range of 790° C. or higher and 870° C. or lower. The conditions of the thermal treatment in the present embodiment can be exemplified by a nitrogen atmosphere, a thermal treatment temperature of 800° C., and a treating time of 30 seconds. By the process such as described above, a semiconductor device 100 having a contact part shown in FIG. 1 can be manufactured.

Table 1 shows an evaluation result of the contact resistance of the contact part in the semiconductor device 100 manufactured as described above. In Examples 1 to 4, the contact resistance was evaluated by changing the film thickness of the Au layer which is the diffusion-preventive layer 142 (diffusion-preventive layer 132). Further, the cross-section of the contact part in each Example was observed with a TEM (Transmission Electron Microscope) and an EDX (Energy Dispersive X-ray spectrometer), and the size of the metal intrusion region 112 was evaluated as a Ti intrusion depth.

TABLE 1

| | | | | | | Characteristic | |
|---|---|---|---|---|---|---|---|
| | Metal film | | | | | contact | Ti intrusion |
| | thickness (nm) | | | | | resistance | depth |
| | Ti | Au | Al | Ni | Au | (Ω/cm²) | (nm) |
| Example 1 | 20 | 60 | 180 | 25 | 30 | 6.9 × 10⁻⁶ | 240 |
| Example 2 | 20 | 30 | 180 | 25 | 30 | 7.4 × 10⁻⁶ | 222 |
| Example 3 | 20 | 20 | 180 | 25 | 30 | 1.2 × 10⁻⁵ | 93 |
| Example 4 | 20 | 10 | 180 | 25 | 30 | 2.9 × 10⁻⁵ | not |
| | | | | | | | evaluated |
| Comparative | 20 | — | 180 | 25 | 30 | 5.9 × 10⁻⁵ | 5 or less |
| Example 1 | | | | | | | |

In Examples 1 to 4, the film thickness of the Ti layer which is the metal layer 140 (metal layer 130) was set to be 20 nm, and the film thickness of the Al layer which is the conductive layer 144 (conductive layer 134) was set to be 180 nm. Further, in Examples 1 to 4, the film thickness of the Ni layer which is the intermediate layer 146 (intermediate layer 136) was set to be 25 nm, and the film thickness of the Au layer which is the cap layer 148 (cap layer 138) was set to be 30 nm. The film thickness of the Au layer which is the diffusion preventive layer 142 (diffusion-preventive layer 132) was set to be 60 nm in Example 1, 30 nm in Example 2, 20 nm in Example 3, and 10 nm in Example 4. The thermal treatment was set to be an RTA treatment under a condition of nitrogen atmosphere, 800° C., and 30 seconds.

With regard to the contact resistance, a characteristic contact resistance by TLM (Transmission Line Model) method was evaluated by two-terminal probing. The Ti intrusion depth was evaluated as the reaching distance in the depth direction of the metal intrusion region 112 by specifying a region having a high Ti concentration as the metal intrusion region 112 from the observation of cross-section by TEM and the observation of a Ti profile by EDX in the same field of view. Further, as Comparative Example 1, those not provided with a diffusion-preventive layer 142 (diffusion-preventive layer 132) were prepared and evaluated in the same manner as in the Examples.

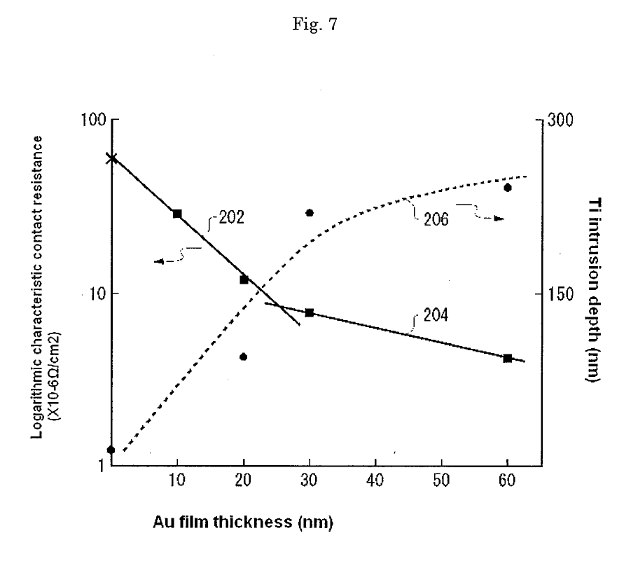

FIG. 7 shows the characteristic contact resistance and the Ti intrusion depth shown in Table 1 as a function of the Au film thickness. The characteristic contact resistance is shown in logarithm. In FIG. 7, the black square plots show a real measured values of the logarithmic characteristic contact resistance, and the black circle plots show real measured values of the Ti intrusion depth. The symbol X represents the characteristic contact resistance value of Comparative Example 1. The solid line 202 and the solid line 204 show experimental lines of the logarithmic characteristic contact resistance, and the broken line 206 shows an experimental curve of the Ti intrusion depth.

From FIG. 7, it will be understood that the characteristic contact resistance decreases as the film thickness of the Au layer which is the diffusion preventive layer 142 (diffusion preventive layer 132) increases. Further, it will be understood that the Ti intrusion depth increases as the Au film thickness increases. The results directly show the effect of the diffusion preventive layer 142 (diffusion preventive layer 132) on the contact resistance decrease, and show that the characteristic contact resistance decreases as the Ti intrusion depth increases.

In addition, the results of FIG. 7 show that the contact resistance can be reduced to about half of that of Comparative Example 1 by the Au film thickness of about 10 nm, and that a great contact resistance reduction effect can be obtained when the Au film thickness is 10 nm or more. Here, the experimental lines of the solid line 202 and the solid line 204 show that an inflection point of the logarithmic characteristic contact resistance exists when the Au film thickness is within a range of 20 to 30 nm. This seems to suggest that the mechanism of the contact resistance reduction changes. A similar suggestion can be read from the fact that the experimental curve of the broken line 206 is inflected with a boundary being around an Au film thickness of 30 nm. In other words, it suggests that, even if the Au film thickness is increased to exceed greatly beyond 60 nm, a large effect of contact resistance reduction can hardly be expected.

From the above, in order to obtain an effect of contact resistance reduction, the film thickness of the Au layer which is the diffusion-preventive layer 142 (diffusion-preventive layer 132) is preferably set to be 10 nm or more, more preferably 25 nm or more, and the upper limit value of the Au film thickness is preferably set to be 500 nm or less in consideration of the facility in processing. By considering that the effect of contact resistance reduction decreases when the Au film thickness is 30 nm or more and further in consideration of the facility in processing, the upper limit value of the Au film thickness is further preferably set to be 200 nm or less, or 80 nm or less.

Table 2 shows a result of evaluation of the contact resistance at the contact part in the semiconductor device 100 manufactured by setting the production condition of the semiconductor device 100 other than the thermal treatment temperature to be the same as that of Example 2. The thermal treatment temperatures of Example 5, Example 6, and Example 7 were set to be respectively 750° C., 850° C., and 900° C.

TABLE 2

| | | | | | | Thermal | Characteristic |
|---|---|---|---|---|---|---|---|
| | Metal film | | | | | treatment | contact |
| | thickness (nm) | | | | | temperature | resistance |
| | Ti | Au | Al | Ni | Au | (° C.) | (Ω/cm²) |
| Example 5 | 20 | 30 | 180 | 25 | 30 | 750 | 4.8 × 10⁻⁵ |
| Example 6 | 20 | 30 | 180 | 25 | 30 | 850 | 4.6 × 10⁻⁶ |
| Example 7 | 20 | 30 | 180 | 25 | 30 | 900 | 8.4 × 10⁻⁵ |

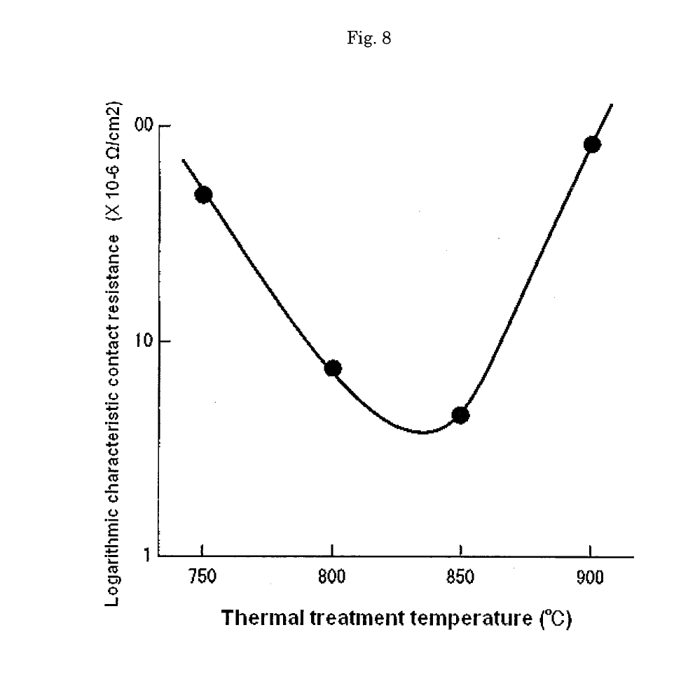

FIG. 8 shows the characteristic contact resistance of Example 2 and Examples 5 to 7 as a function of the thermal treatment temperature. The black circle plots show real measured values, and the solid line shows an experimental curve. From FIG. 8, it will be understood that there is an optimal thermal treatment temperature for reducing the characteristic contact resistance. The thermal treatment temperature is preferably within a temperature range of 750° C. or higher and 900° C. or lower, more preferably within a temperature range of 790° C. or higher and 870° C. or lower.

TABLE 3

| | | | Characteristic | Ti |
|---|---|---|---|---|
| | | AlGaN film | contact | intrusion |
| | Al | thickness | resistance | depth |
| | composition | (nm) | (Ω/cm²) | (nm) |
| Example 8 | 0.465 | 21.5 | 2.2 × 10⁻⁵ | 64 |
| Example 9 | 0.240 | 28.0 | 9.1 × 10⁻⁷ | 240 |
| Example 10 | 0.000 | — | 2.9 × 10⁻⁶ | — |
| Comparative | 0.465 | 21.5 | 1 × 10⁻³ or more | 5 or less |
| Example 2 | | | | |
| Comparative | 0.000 | — | 3.7 × 10⁻⁶ | — |
| Example 3 | | | | |

Table 3 shows an evaluation result of the contact resistance of the contact part in the semiconductor device 100 and the Ti intrusion depth. In Table 3, Example 8 is an example of a semiconductor device 100 produced under the same production condition as in Example 1 by using a substrate (epitaxial substrate for HEMT) on which an AlGaN layer having an Al composition of 0.465 has been formed. The epitaxial substrate for HEMT is available, for example, as an AlGaN/GaN Epiwafer (trade name) of NTT advance technology Co., Ltd.

In Table 3, Example 9 is an example of a semiconductor device 100 produced under the same production condition as in Example 1 by using a substrate (epitaxial substrate for HEMT) on which an AlGaN layer having an Al composition of 0.24 has been formed. In Table 3, Example 10 is an example of a semiconductor device 100 produced under the same production condition as in Example 1 by using as epitaxial substrate with the Al composition being zero. The epitaxial substrate of Example 10 was let to have a conductivity type of n-type. The concentration of Si giving the n-type was controlled to be 2.0×10¹⁸ cm⁻³.

With regard to the contact resistance, a characteristic contact resistance by TLM (Transmission Line Model) method was evaluated by four-terminal probing. The Ti intrusion depth was evaluated as the reaching distance in the depth direction of the metal intrusion region 112 by specifying a region having a high Ti concentration as the metal intrusion region 112 from the observation of cross-section by TEM and the observation of a Ti profile by EDX in the same field of view.

As Comparative Example 2, a semiconductor device was produced under the same production condition as in Comparative Example 1 of Table 1 by using a substrate (epitaxial substrate for HEMT) on which an AlGaN layer having an Al composition of 0.465 has been formed.

As Comparative Example 3, a semiconductor device was produced under the same production condition as in Comparative Example 1 of Table 1 by using an epitaxial substrate with the Al composition being zero. The epitaxial substrate of Comparative Example 3 was let to have a conductivity type of n-type in the same manner as in Example 10. Comparative Example 2 and Comparative Example 3 were evaluated in the same manner as Examples 8 to 10.

Because of realizing a wide band gap, a substrate (epitaxial substrate for HEMT) on which an AlGaN layer having an Al composition of 0.35 or more has been formed is expected to be a practically advantageous substrate; however, it is expected that the contact resistance will be large. But, by using the technique of the present embodiment, as shown in Example 8 of Table 3, even if a substrate (epitaxial substrate for HEMT) on which an AlGaN layer having an Al composition of 0.35 or more has been formed is used, the contact resistance can be reduced to a resistance value of the same degree as that of a conventional semiconductor device 100 having an Al composition of about 0.24 shown in Example 9. Further, it is expected that, even if a substrate (epitaxial substrate for HEMT) on which an AlGaN layer having a larger Al composition has been formed is used, the contact resistance can be reduced to a resistance value of the same degree as that of a conventional semiconductor device 100 having an Al composition of about 0.24. That is, the technique of the present embodiment can realize both a wide band gap and an ohmic connection having a low contact resistance.

Further, the following matters can be considered from the comparison result of each characteristic contact resistance of Example 8 and Comparative Example 2, Example 1 and Comparative Example 1, and Example 10 and Comparative Example 3 in which the Al compositions are respectively 0.465, 0.24, and 0. That is, when comparison is made on Example 8 and Comparative Example 2 in which the Al composition is 0.465, the contact resistance of Example 8 is smaller by about 10⁻² times than the contact resistance of Comparative Example 2. When comparison is made on Example 1 and Comparative Example 1 in which the Al composition is 0.24, the contact resistance of Example 1 is smaller by about 10⁻¹ times than the contact resistance of Comparative Example 1. Further, when comparison is made on Example 10 and Comparative Example 3 using an epitaxial substrate for HEMT in which the Al composition is zero and an AlGaN layer is not formed, the contact resistance of Example 10 is smaller by about 0.8 times than the contact resistance of Comparative Example 3.

The above results show that, even with a case in which an epitaxial substrate for HEMT having any Al composition is used, the contact resistance has been reduced by application of the technique of the present embodiment, and that the effect produced by the technique of the present embodiment increases as the Al composition becomes larger. That is, the degree of decrease in the contact resistance of the Example to which the technique of the present embodiment is applied from the Comparative Example will be larger to 0.8 times, to 0.1 times, and to 0.01 times as the Al composition increases to become 0, 0.24, and 0.465. In addition, even in a case in which the Al composition becomes further larger by exceeding 0.465, it is expected that the degree of decrease in the contact resistance will be further larger.

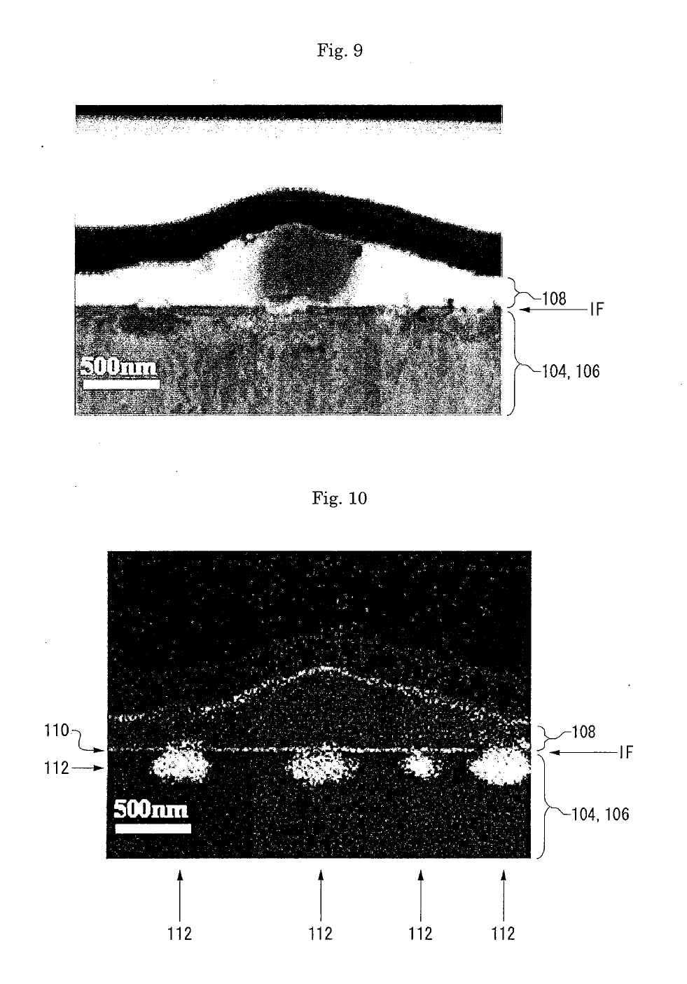

FIG. 9 shows a TEM image obtained by observing the contact part of the semiconductor device 100 by the production condition of Example 2. Since the boundary between the first semiconductor layer 104 and the second semiconductor layer 106 is hardly recognizable, they are denoted with a symbol by being assumed to be the same region; however, the second semiconductor layer 106 is formed as an upper layer to the first semiconductor layer 104. A conductive layer 108 is formed as an upper layer to the second semiconductor layer 106. An interface IF is formed at the boundary between the second semiconductor layer 106 and the conductive layer 108.

FIG. 10 shows a Ti mapping image by EDX with the same field of view as the TEM image of FIG. 9. It will be displayed more in white as the Ti concentration is larger. From FIG. 9, it will be understood that a region displayed in white, that is, a metal-distributed region 110, is formed at the interface IF between the second semiconductor layer 106 and the conductive layer 108. Further, it will be understood that a circular region displayed in white, that is, a metal intrusion region 112, is formed in a region of the first semiconductor layer 104 and the second semiconductor layer 106. As shown in FIG. 10, the metal intrusion region 112 is formed non-uniformly in a plane to which the interface IF belongs.

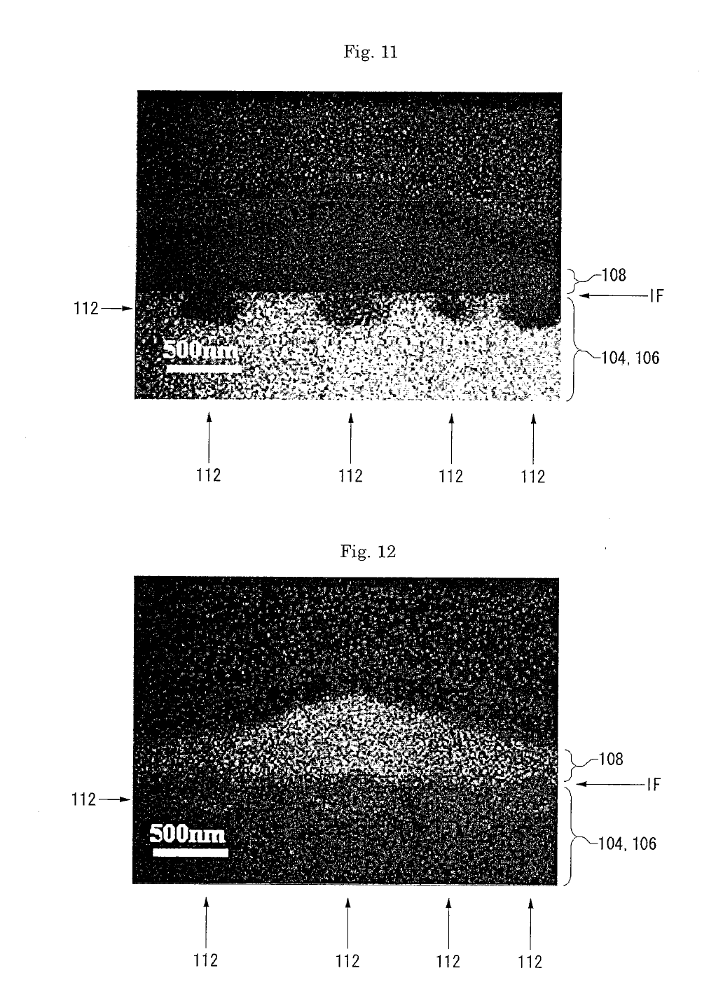

FIG. 11 shows a Ga mapping image by EDX with the same field of view as the TEM image of FIG. 9. It will be displayed more in white as the Ga concentration is larger. From FIG. 11, it will be understood that the Ga concentration of the region in which the metal intrusion region 112 is formed decreases. The decrease in the Ga concentration in the metal intrusion region 112 in the present Example 2 is measured to decrease to 10 to 43% as compared with the region that is not the metal intrusion region 112.

FIG. 12 shows an Al mapping image by EDX with the same field of view as the TEM image of FIG. 9. It will be displayed more in white as the Al concentration is larger. From FIG. 12, it will be understood that the surroundings of the metal intrusion region 112 is surrounded by Al.

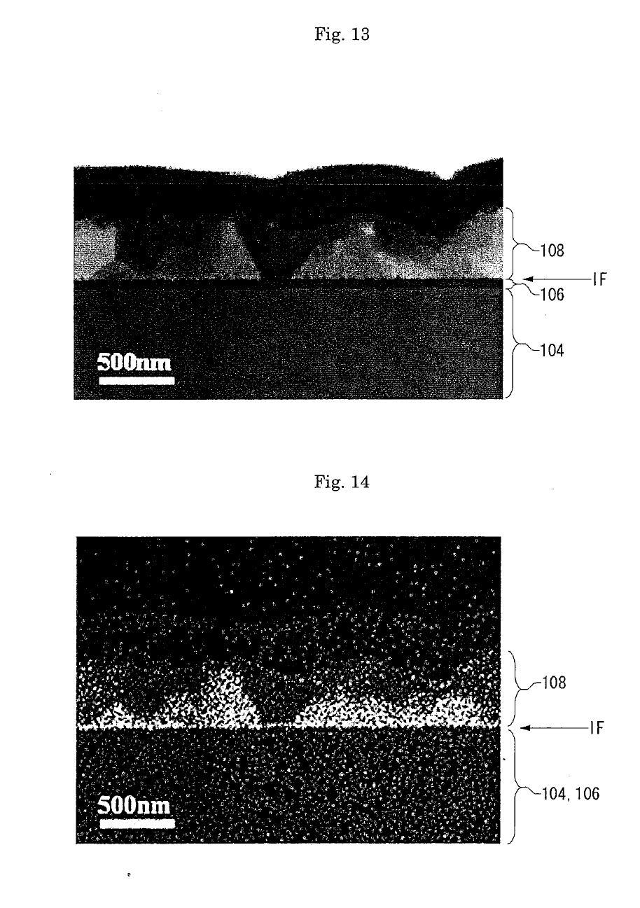

FIG. 13 shows a TEM image in Comparative Example. In FIG. 13, since the boundary between the first semiconductor layer 104 and the second semiconductor layer 106 can be distinguished, they are displayed by being denoted with different symbols. In the same manner as in FIG. 9, a conductive layer 108 is formed on the second semiconductor layer 106, and an interface IF is formed at the boundary between the second semiconductor layer 106 and the conductive layer 108.

FIG. 14 shows a Ti mapping image by EDX with the same field of view as the TEM image of FIG. 13. It will be displayed more in white as the Ti concentration is larger. It will be understood that, in Comparative Example 1, the metal intrusion region 112 such as shown in FIG. 10 is not formed. This fact also strongly supports that the reduction of contact resistance is derived from formation of the metal intrusion region 112. Here, the Ti intrusion depth in Comparative Example 1 is observed to be 5 nm or less.

Further, as shown in FIG. 14, the region having a high Ti concentration is formed in the conductive layer 108 in Comparative Example 1. On the other hand, as shown in FIG. 10, the region having a high Ti concentration is formed not in the conductive layer 108 but in the first semiconductor layer 104 and in the second semiconductor layer 106 in Example 2. Namely, in Example 2, Ti exists in a larger amount in the first semiconductor layer 104 and in the second semiconductor layer 106 than in the conductive layer 108. By comparing FIG. 14 and FIG. 10, it will be understood that, by the presence of the Au layer which is a diffusion-preventive layer 142 (diffusion-preventive layer 132), the diffusion of Ti into the conductive layer 108 is restrained, and meanwhile, implantation of Ti into the first semiconductor layer 104 and into the second semiconductor layer 106 has occurred.

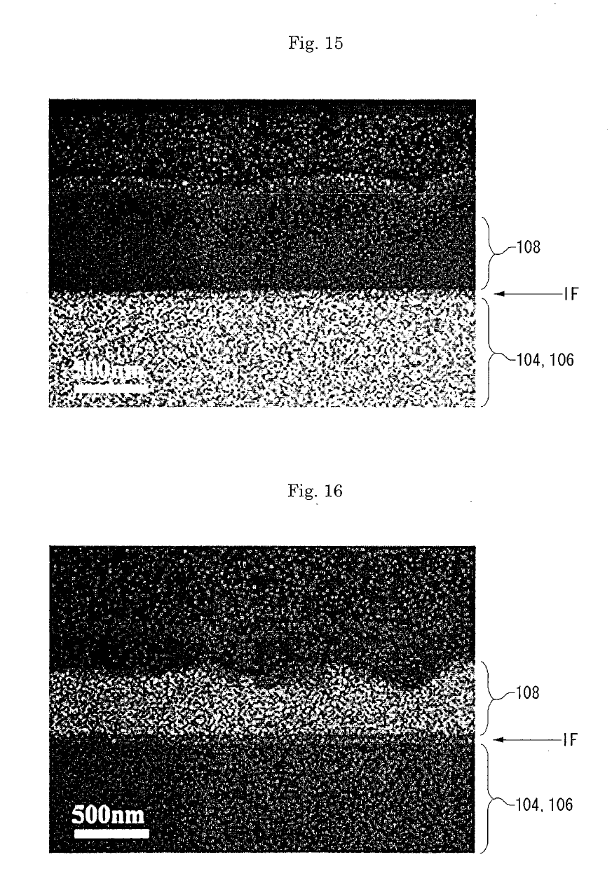

FIG. 15 shows a Ga mapping image by EDX with the same field of view as the TEM image of FIG. 13. It will be displayed more in white as the Ga concentration is larger. Further, FIG. 16 shows an Al mapping image by EDX with the same field of view as the TEM image of FIG. 13. It will be displayed more in white as the Al concentration is larger. In FIGS. 15 and 16, it will be understood that an element profile characteristic to the metal intrusion region 112 such as shown in FIGS. 11 and 12 is not displayed at all.

According to the semiconductor device 100 of the present embodiment described above, the metal-distributed region 110 and the metal intrusion region 112 are formed in the contact part to the semiconductor layer under the conductive layer 108. Accordingly, the contact resistance at the contact part is considerably reduced. Here, it is a natural result from that the above described effect is obtained by the fact that a characteristic conductive region called the metal intrusion region 112 is formed at the interface between the semiconductor and the conductive layer (electrode), and it includes a possibility that the contact resistance can be further reduced by optimizing the thermal treatment condition and the like.

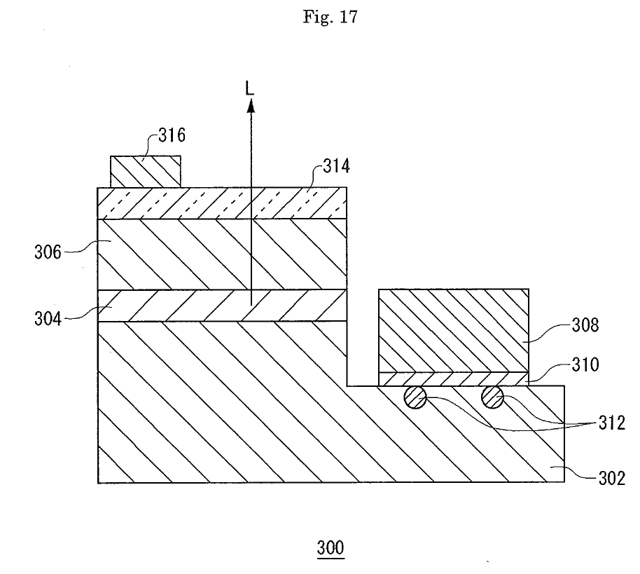

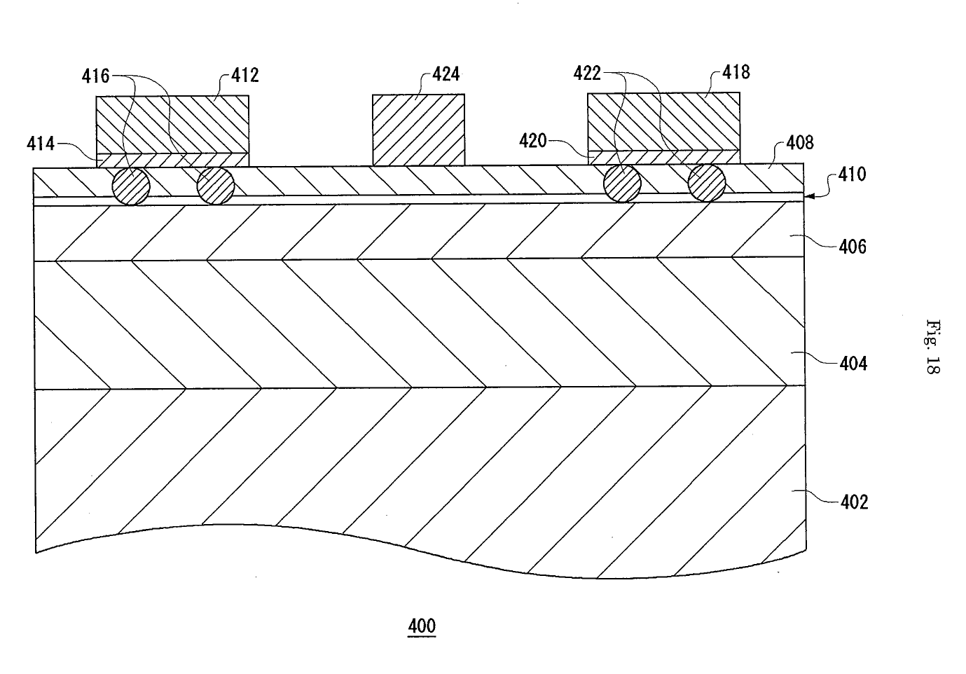

FIG. 17 shows a light emitting device 300 as one example of the semiconductor device 100 of the present embodiment. The light emitting device 300 includes a first semiconductor layer 302, a second semiconductor layer 304, a third semiconductor layer 306, an electrode 308, a metal-distributed region 310, a metal intrusion region 312, a transparent electrode 314, and a contact pad 316.

The first semiconductor layer 302 may be a semiconductor layer of n-type, for example, as a first conductivity type, including N and Ga. The second semiconductor layer 304 may be a semiconductor layer, for example, of n-type including N and Ga that forms a first hetero-junction with the first semiconductor layer 302. The second semiconductor layer 304 generates radiation light by recombination of carriers. The third semiconductor layer 306 may be a semiconductor layer of p-type, for example, as a second conductivity type, including N and Ga that forms a second hetero-junction with the second semiconductor layer 304.

The electrode 308 is ohmic-connected to the first semiconductor layer 302. The metal-distributed region 310 exists with a metal, for example, Ti, distributed at an interface between the first semiconductor layer 302 and the electrode 308. The metal intrusion region 312 is such that atoms of a metal, for example, Ti, exist by entering the first semiconductor layer 302. The transparent electrode 314 is formed to be in contact with the third semiconductor layer 306, and the contact pad 316 is in contact with the transparent electrode 314.

In the light emitting device 300, recombination of carriers occurs in the second semiconductor layer 304 by passing an electric current between the electrode 308 and the transparent electrode 314, whereby light is emitted. In the light emitting device 300, the metal-distributed region 310 and the metal intrusion region 312 are formed between the electrode 308 and the first semiconductor layer 302. For this reason, the contact resistance of ohmic contact can be reduced. In the light emitting device 300, reduction of electric power consumption, reduction of generated heat amount, and improvement of light emission efficiency are demanded, so that an effect satisfying these demands can be expected by reduction of the contact resistance.

Here, in place of the transparent electrode 314, an electrode similar to the electrode 308 can be constructed. Namely, the electrode disposed in place of the transparent electrode 314 may be ohmic-connected to the third semiconductor layer 306, and a metal-distributed region may be formed at an interface between the third semiconductor layer 306 and the electrode disposed in place of the transparent electrode 314. Further, Ti, for example, may be allowed to enter the third semiconductor layer 306 to form a metal intrusion region. In addition, the metal intrusion region 312 may be formed to reach an interface of the first hetero-junction or the second hetero-junction.

FIG. 18 shows a high carrier mobility transistor 400 as one example of the semiconductor device 100 of the present embodiment. The high carrier mobility transistor 400 includes a substrate 402, a buffer layer 404, a non-doped semiconductor layer 406 formed on the substrate 402 and including N and Ga, a doped semiconductor layer 408 doped with an impurity having a larger band gap than the non-doped semiconductor layer 406 and forming a hetero-junction with the non-doped semiconductor layer 406, a channel region 410 formed at a hetero-junction interface between the non-doped semiconductor layer 406 and the doped semiconductor layer 408, a gate electrode 424 Schottky-connected to the doped semiconductor layer 408, a source electrode 412 ohmic-connected to the doped semiconductor layer 408, a drain electrode 418 ohmic-connected to the doped semiconductor layer 408, a metal-distributed region 414 where metal is distributed at an interface between the doped semiconductor layer 408 and the source electrode 412 and exists, a metal intrusion region 416 where the atoms of the metal exist by entering the doped semiconductor layer 408, a metal-distributed region 420 where metal exists by being distributed at an interface between the doped semiconductor layer 408 and the drain electrode 418, and a metal intrusion region 422 where the atoms of the metal exist by entering the doped semiconductor layer 408.

According to the high carrier mobility transistor 400, the metal-distributed region 414 and the metal intrusion region 416 are formed at an interface between the source electrode 412 and the doped semiconductor layer 408. Further, the metal-distributed region 420 and the metal intrusion region 422 are formed at an interface between the drain electrode 418 and the doped semiconductor layer 408. As a result of this, the on-resistance between the source and drain can be reduced. In the high carrier mobility transistor 400 operating in a high-frequency region, the reduction of on-resistance produces a particularly great effect in ensuring a high-frequency operation. Here, the metal intrusion region 416 and the metal intrusion region 422 may be formed to reach the channel region 410.

As shown above, the present invention has been described with reference to the embodiments; however, the technical scope of the present invention is not limited to the range described in the above embodiments. It will be clear to those skilled in the art that various changes or modifications can be added to the above-described embodiments. It will be clear from the scope of the claims that the embodiments to which such changes or modifications have been added are also comprised within the technical scope of the present invention.

### INDUSTRIAL APPLICABILITY

According to the present invention, a semiconductor device that reduces the contact resistance of an electrode that is ohmic-connected to a semiconductor layer, a method of manufacturing the semiconductor device, a high carrier mobility transistor, and a light emitting device are provided.

1. A semiconductor device comprising:
a semiconductor layer including N and Ga;
a conductive layer ohmic-connected to the semiconductor layer;
a metal-distributed region where metal exists by being distributed at an interface between the semiconductor layer and the conductive layer; and
a metal intrusion region where the atoms of the metal exist by entering the semiconductor layer.

2. The semiconductor device according to claim 1, wherein the metal intrusion region is formed non-uniformly in a plane parallel to the interface in the semiconductor layer.

3. The semiconductor device according to claim 1, wherein the metal intrusion region is formed to reach a region having an intrusion depth of 6 nm or more in the semiconductor layer.

4. The semiconductor device according to claim 1, wherein the semiconductor layer has a hetero-junction interface of semiconductors including N and Ga, and the metal intrusion region is formed to reach the hetero-junction interface.

5. The semiconductor device according to claim 1, wherein the semiconductor layer has a hetero-junction interface of semiconductors including N and Ga, and the metal intrusion region is formed in a region of the semiconductor layer that does not reach the hetero-junction interface.

6. The semiconductor device according to claim 1, wherein the metal exists more in the metal intrusion region as compared with the conductive layer.

7. The semiconductor device according to claim 1, wherein a concentration of the metal in the metal intrusion region is within a range of 1% or more and 100% or less in terms of molar fraction.

8. The semiconductor device according to claim 1, wherein a concentration of Ga in the metal intrusion region is lower than a concentration of Ga in the semiconductor layer other than the metal intrusion region.

9. The semiconductor device according to claim 8, wherein the concentration of Ga in the metal intrusion region is lower than the concentration of Ga in the semiconductor layer other than the metal intrusion region by 50% or more.

10. The semiconductor device according to claim 1, wherein the semiconductor layer includes a group III element constituting a mixed crystal by replacing Ga, and the group III element exists by surrounding the metal intrusion region in the semiconductor layer.

11. The semiconductor device according to claim 10, wherein the group III element is Al.

12. The semiconductor device according to anyone of claim 1, further comprising a conductive cap layer formed on the conductive layer to prevent oxidation of the conductive layer and a conductive intermediate layer formed between the conductive layer and the cap layer.

13. The semiconductor device according to anyone of claim 1, wherein the metal is Ti.

14. The semiconductor device according to claim 13, wherein the Ti constitutes TiN by being bound with N included in the semiconductor layer.

15. The semiconductor device according to anyone of claim, wherein a main component of the conductive layer is Al.

16. The semiconductor device according to claim 1, where the metal-distributed region and the metal intrusion region are formed by successively forming a meta layer including the metal as a main component, a diffusion-preventive layer for preventing diffusion of the metal, and the conductive layer on the semiconductor layer, and thermally treating the meal layer, the diffusion-preventive layer, and the conductive layer.

17. The semiconductor device according to claim 16, wherein a material constituting the diffusion-preventive layer has a melting point higher than a melting point of a material constituting the conductive layer.

18. A method of manufacturing a semiconductor device, comprising:
a step of forming a semiconductor layer including N and Ga;
a step of forming a metal layer as an upper layer to the semiconductor layer,
a step of forming a diffusion-preventive layer for preventing diffusion of a metal constituting the metal layer on the metal layer;
a step of forming a conductive layer as an upper layer to the diffusion-preventive layer; and
a step of thermally treating the semiconductor layer, the metal layer, the diffusion-preventive layer, and the conductive layer.

19. The method of manufacturing a semiconductor device according to claim 18, wherein a material constituting the diffusion-preventive layer has a melting point higher than a melting point of a material constituting the conductive layer.

20. The method of manufacturing a semiconductor device according to claim 18, further comprising a step of forming a conductive intermediate layer and a conductive cap layer for preventing oxidation of the conductive layer after forming the conductive layer.

21. The method of manufacturing a semiconductor device according to anyone of claim 18, wherein a metal mainly constituting the metal layer is Ti.

22. The method of manufacturing a semiconductor device according to any one of claim 18, wherein a material mainly constituting the conductive layer is A1.

23. The method of manufacturing a semiconductor device according to any one of claim 18, wherein a material mainly constituting the diffusion-preventive layer is any material selected from Au, Ag, Cu, W, Mo, Cr, Nb, Pt, Pd, and Si, an alloy of these, or a nitride or oxide of these.

24. The method of manufacturing a semiconductor device according to claim 23, wherein a material mainly constituting the diffusion preventive layer is Au.

25. The method of manufacturing a semiconductor device according to claim 24, wherein the diffusion preventive layer is formed to have a film thickness of 10 nm or more and 500 nm or less, preferably 15 nm or more and 200 nm or less, more preferably 25 nm or more and 80 nm or less.

26. The method of manufacturing a semiconductor device according to claim 25, wherein the thermal treatment is carried out within a temperature range of 650° C. or higher and 900° C. or lower.

27. A high carrier mobility transistor comprising:
a substrate;
a non-doped semiconductor layer formed as an upper layer to the substrate and including N and Ga;
a doped semiconductor layer doped with an impurity having a larger band gap than the non-doped semiconductor layer and forming a hetero-junction with the non-doped semiconductor layer;
a channel region formed at a hetero-junction interface between the non-doped semiconductor layer and the doped semiconductor layer;
a gate electrode Schottky-connected to the doped semiconductor layer;
a source electrode and a drain electrode that are ohmic-connected to the doped semiconductor layer;
a metal-distributed region where metal exists by being distributed at an interface between the doped semiconductor layer and the source electrode and between the doped semiconductor layer and the drain electrode; and
a metal intrusion region where the atoms of the metal exist by entering the doped semiconductor layer.

28. A high carrier mobility transistor according to claim 27, wherein the metal intrusion region is formed to reach the channel region.

29. A light emitting device comprising:
a first semiconductor layer of first conductivity type including N and Ga;
a second semiconductor layer of first conductivity type including N and Ga and forming a first hetero-junction with the first semiconductor layer to generate radiation light by recombination of carriers;
third semiconductor layer of second conductivity type including N and GA and forming a second hetero-junction with the second semiconductor layer;
an electrode ohmic-connected to the first semiconductor layer or the third semiconductor layer;
a metal-distributed region where metal exists by being distributed at an interface between the first semiconductor layer or the third semiconductor layer and the electrode; and
a metal intrusion region where the atoms of the metal exist by entering the first semiconductor layer or the third semiconductor layer.

30. The light emitting device according to claim 29, wherein the metal intrusion region is formed to reach an interface of the first hetero-junction or the second hetero-junction.
